(19) United States
(12) Patent Application Publication
(10) Pub. No.: US 2009/0146249 A1
(43) Pub. Date: Jun. 11, 2009

(54) SEMICONDUCTOR STRUCTURE AND METHOD OF MANUFACTURE

(76) Inventors: Bishnu P. Gogoi, Scottsdale, AZ (US); Michael A. Tischler, Phoenix, AZ (US); David William Wolfert, JR., Tempe, AZ (US)

Correspondence Address: HVVI SEMICONDUCTORS, INC., c/o CPA Global, P.O. BOX 52050, MINNEAPOLIS, MN, 55402, US

(21) Appl. No.: 12/330,750

(22) Filed: Dec. 9, 2008

Related U.S. Application Data
(60) Provisional application No. 61/012,875, filed on Dec. 11, 2007.

(51) Int. Cl. H01L 21/76; H01L 23/00

(52) U.S. Cl. 257/522; 438/422; 257/E21.54; 257/E23.001

(57) ABSTRACT

In various embodiments, semiconductor structures and methods to manufacture these structures are disclosed. In one embodiment, a method to form a semiconductor structure includes removing a portion of a semiconductor material to form one or more suspended structures and a cavity, the cavity having a boundary that is below a surface of the semiconductor material and wherein the one or more suspended structures extend from the surface into the cavity. The method further includes altering the one or more suspended structures to form one or more altered suspended structures and forming a material over the one or more altered suspended structures and in a region between the one or more altered suspended structures. Other embodiments are described and claimed.

### TECHNICAL FIELD

Embodiments disclosed in the present disclosure relate generally to electrical and semiconductor technology, and more specifically to a semiconductor structure that includes a dielectric structure.

### BACKGROUND

For some applications, such as high frequency or radio frequency (“RF”) applications, it may be possible to form integrated passive devices using semiconductor processing technology or it might be possible to integrate passive devices such as inductors and/or capacitors together with active devices such as transistors using a conductive silicon substrate such as, for example, a semiconductor die. However, passive devices may have relatively low quality factors (“Qs”) when these passive devices are formed on, or in relatively close proximity to, the conductive silicon substrate. In addition, due to parasitic capacitive coupling between these passive devices and the conductive silicon substrate, the frequency of operation of the integrated devices is limited. Electrically conductive interconnects or busses may be used to electrically couple different devices within the die and external to the die. The frequency of operation may also be reduced by parasitic capacitive coupling between the interconnects and the conductive silicon substrate.

Further, in some digital, analog, or radio frequency (RF) transistor applications, it may be possible to physically and electrically isolate regions of a semiconductor substrate from each other. Additionally, some semiconductor devices, such as power transistors, provide a relatively high output power, which may be utilized in some radio frequency (“RF”), industrial, and medical applications. Power transistor designers are continually seeking ways to efficiently increase output power by varying the output voltage and current characteristics of a power transistor. For example, it may be possible to have a power transistor that has an increased breakdown voltage to enable the power transistor to operate at a relatively higher voltage and provide a relatively higher output power.

Accordingly, it is contemplated to have improved semiconductor structures, and methods to make these structures, that may provide for reduced parasitic capacitances, relatively higher frequencies of operation, relatively higher breakdown voltages, relatively higher quality factor passive devices, increased isolation, or combinations thereof.

### BRIEF DESCRIPTION OF THE DRAWINGS

FIG. 1 is a cross-sectional view of a semiconductor structure in accordance with an embodiment of the present invention;

FIG. 2 is a cross-sectional view of the semiconductor structure of FIG. 1 at an earlier stage of manufacture;

FIG. 3 is a cross-sectional view of the semiconductor structure of FIG. 2 at a later stage of manufacture;

FIG. 4 is a cross-sectional view of the semiconductor structure of FIG. 3 at a later stage of manufacture;

FIG. 5 is a top view of the semiconductor structure of FIG. 4;

FIG. 6 is a cross-sectional view of the semiconductor structure of FIGS. 4 and 5 at a later stage of manufacture;

FIG. 7 is a cross-sectional view of the semiconductor structure of FIG. 6 at a later stage of manufacture;

FIG. 8 is a cross-sectional view of the semiconductor structure of FIG. 7 at a later stage of manufacture;

FIG. 9 is a cross-sectional view of another semiconductor structure in accordance with another embodiment of the present invention;

FIG. 10 is a cross-sectional view of the semiconductor structure of FIG. 9 at an earlier stage of manufacture;

FIG. 11 is a cross-sectional view of the semiconductor structure of FIG. 10 at a later stage of manufacture;

FIG. 12 is a cross-sectional view of the semiconductor structure of FIG. 11 at a later stage of manufacture;

FIG. 13 is a cross-sectional view of the semiconductor structure of FIG. 12 at a later stage of manufacture;

FIG. 14 is a cross-sectional view of the semiconductor structure of FIG. 13 at a later stage of manufacture;

FIG. 15 is a cross-sectional view of another semiconductor structure in accordance with another embodiment of the present invention;

FIG. 16 is a cross-sectional view of the semiconductor structure of FIG. 15 at an earlier stage of manufacture;

FIG. 17 is a cross-sectional view of the semiconductor structure of FIG. 16 at a later stage of manufacture;

FIG. 18 is a cross-sectional view of the semiconductor structure of FIG. 17 at a later stage of manufacture; and

FIG. 19 is a top view of the semiconductor structure of FIG. 11 in accordance with an embodiment of the present invention.

For simplicity of illustration and ease of understanding, elements in the various figures are not necessarily drawn to scale, unless explicitly so stated. Further, if considered appropriate, reference characters have been repeated among the figures to indicate corresponding and/or analogous elements.

### DETAILED DESCRIPTION

In some instances, well-known methods, procedures, components and circuits have not been described in detail so as not to obscure the present disclosure. The following detailed description is merely exemplary in nature and is not intended to limit the disclosure of this document and uses of the disclosed embodiments. Furthermore, there is no intention that the appended claims be limited by the title, technical field, background, or abstract.

In the following description and claims, the terms “comprise” and “include,” along with their derivatives, may be used and are intended as synonyms for each other. In addition, in the following description and claims, the terms “coupled” and “connected,” along with their derivatives, may be used. “Connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. For example, “coupled” may mean that two or more elements do not contact each other but are indirectly joined together via another element or intermediate elements. Finally, the terms “on,” “overlying,” and “over” may be used in the following description and claims. “On,” “overlying,” and “over” may be used to indicate that two or more elements are in direct physical contact with each other. However, “over” may also mean that two or more elements are not in direct contact with each other. For example, “over” may mean that one element is above another element but not contact each other and may have another element or elements in between the two elements.

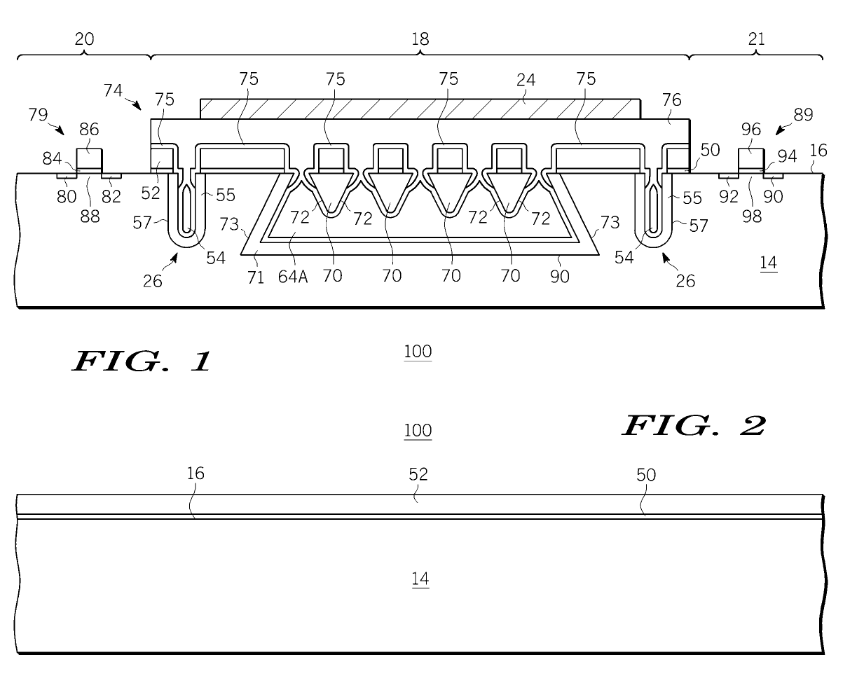

FIG. 1 is a cross-sectional view of a semiconductor structure 100 that illustrates a dielectric platform (“DP”) 18, active regions 20 and 21, and an electrically conductive material 24 in accordance with an embodiment of the present invention. Dielectric platform 18 may be referred to as a dielectric structure or a dielectric region, and active regions 20 and 21 may also be referred to as active area regions, active areas, or portions of the active areas since active devices, or portions of active devices, typically are formed in active regions 20 and 21.

Dielectric platform 18 of semiconductor structure 100 comprises a plurality of dielectric structures 70 formed in a substrate 14 having a boundary or top surface 16. Although not shown, substrate 14 also has an opposing boundary or bottom surface that is parallel to, or substantially parallel to, top surface 16. In other embodiments of the present invention, structures 70 may be elongated partitions or dividers that extend from surface 16 into a sealed cavity 64A. Thus, structures 70 may be referred to as hanging structures, hanging partitions, hanging dividers, hanging walls vertically oriented hanging structures, or the like. Structures 70 may comprise silicon dioxide, thus they may be referred to as hanging dielectric structures. In some embodiments, thermal oxidation may be performed to convert a portion of substrate 14 to silicon dioxide, thereby forming silicon dioxide layer or region 71 which may include hanging dielectric structures 70. In addition to dielectric region 71, dielectric platform 18 shown in FIG. 1 includes a capping structure 74, sealed cavity 64A, and dielectric layers 50 and 52. Dielectric platform 18 may include a termination structure 26 that comprises a trench 54, a dielectric layer 55, and sidewalls 57. Termination structure is adjacent a periphery of cavity 64A.

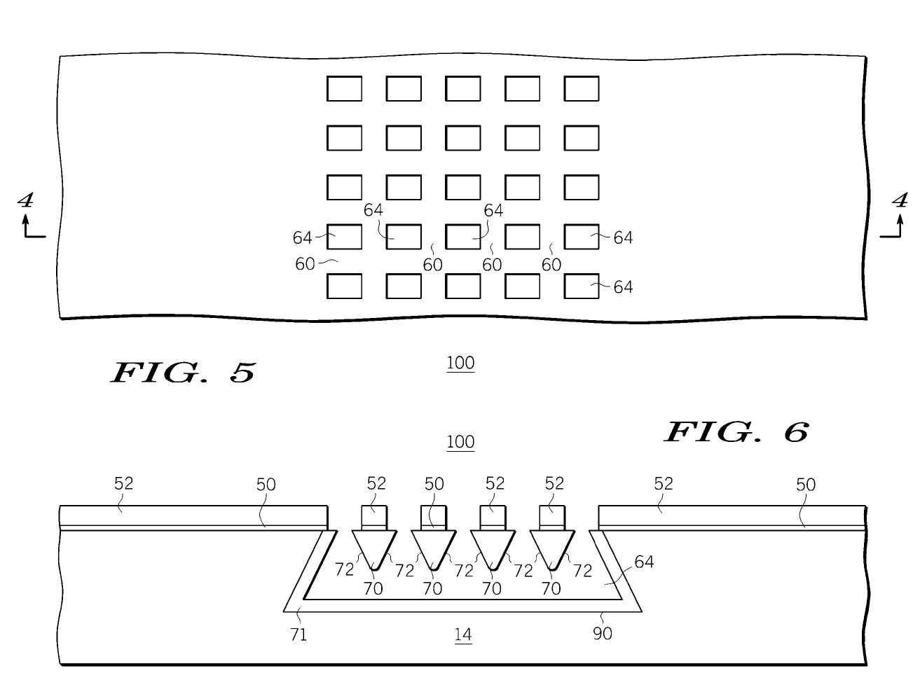

A cavity 64 (FIGS. 4 and 5) having a floor 66 (FIG. 4) extends from top surface 16 into substrate 14. Structures 60 (FIG. 4) extend from top surface 16 into cavity 64 (FIGS. 4 and 5). Cavity 64 may also be referred to as a void, a gap, an air gap, an opening, an empty region, a trench, an empty space, or the like. In addition, as described herein, in some embodiments of the present invention, cavity 64 may be capped, covered, or sealed and also may be hermetically sealed to prevent any contamination from undesirable particles, gasses, or moisture that may propagate into, or get trapped in, cavity 64. When capped, the cavity is identified by reference character 64A and may be referred to as a sealed cavity, a sealed gap, a sealed void, a closed cell, or a closed cell void. In some embodiments, sealed cavity 64A is evacuated to a pressure less than atmospheric pressure. In other words, the pressure in sealed cavity 64A is below atmospheric pressure. As an example, the pressure in sealed cavity 64A may range from approximately 0.1 Torr to approximately 10 Torr. The type of substance or material within sealed cavity 64A is not a limitation of the present invention. For example, sealed cavity 64A may contain a solid material or a fluid such as a liquid or a gas.

Capping structure 74 is formed over hanging dielectric structures 70 and cavity 64 and seals cavity 64 to form a sealed cavity 64A. Capping structure 74 is also referred to as a capping layer and may comprise, for example, a layer 76 formed on a layer 75. Layer 75 is a non-conformal layer of dielectric material that decreases the distance between structures 70. In other words, layer 75 reduces the openings between dielectric hanging structures 70. Layer 75 may be an oxide formed by plasma enhanced chemical vapor deposition (“PECVD”), plasma assisted chemical vapor deposition (“PACVD”), atmospheric pressure chemical vapor deposition (“APCVD”), subatmospheric chemical vapor deposition (“SACVD”), laser assisted chemical deposition, sputtering, reduced pressure chemical vapor deposition (“RPCVD”), or the like. In other embodiments, layer 75 may be an oxide formed using tetraethylorthosilicate (“TEOS”), phosphosilicate glass (PSG), borophosphosilicate glass (“BPSG”), borosilicate glass (“BSG”), silicon nitride, or silicon oxynitride, Layer 76 is a conformal layer that seals cavity 64. In other words, conformal layer 76 may fill any openings or cracks in layer 75, and in general prevent the propagation of gases or moisture into sealed cavity 64A. By way of example, sealing layer 76 is silicon nitride formed by low pressure chemical vapor deposition (LPCVD). In other embodiments, sealing layer 76 may be LPCVD low temperature oxide (LTO), LPCVD high temperature oxide (HTO), LPCVD TEOS, or LPCVD PSG. Capping structure 74 may have a thickness ranging from about 1,000 Angstroms (“Å”) to about 4 microns (“μm”). In some embodiments, due to the relatively small openings between the upper portions of dielectric hanging structures 70, capping structure 74 may enter into a portion of sealed cavity 64A or a region between the upper portions of adjacent dielectric hanging structures 70, but not fill sealed cavity 64A due in part to the relatively small size of the openings between the upper portions of dielectric hanging structures 70.

An optional dielectric termination structure 26 comprising a trench 54 and a dielectric layer 55 may be formed in substrate 14. In some embodiments dielectric layer 55 may comprise silicon dioxide. In addition, termination structure 26 may include a portion of capping structure 74. Dielectric termination structure 26 may be part of dielectric platform 18 or may be laterally spaced apart from dielectric platform 18. In other embodiments, trench 54 may be filled with one or more dielectric materials (not shown) such as, for example, an oxide, a nitride, or an undoped polysilicon. Termination structure 26 has sidewalls 57 that are perpendicular, or substantially perpendicular, to top surface 16 of substrate 14. Termination structure 26 may serve as termination for field lines such as, for example, equipotential lines, during depletion of active devices formed in active regions 20 and 21. Thus, as is discussed further below, equipotential lines impinge on dielectric sidewalls 57. In other words, termination structure 26 may provide termination for equipotential lines from an electric field in an active region formed adjacent to termination structure 26. It may be desirable for sidewalls 57 to be straight and smooth so that the equipotential lines are substantially perpendicular to sidewalls 57 to achieve a condition, referred to as planar breakdown, at which equipotential lines terminate at a perpendicular angle, or a substantially perpendicular angle, to sidewalls 57. Equipotential lines that impinge on sidewalls 57 at an angle that is not perpendicular to sidewalls 57 may decrease the breakdown voltage of active devices formed in active region 20, active region 21, or both.

As is discussed below, active devices, or portions of active devices, are formed in or from substrate 14. Substrate 14 may comprise a semiconductor material and active regions 20 and 21 may be formed in the semiconductor material of substrate 14. In some embodiments, semiconductor material 14 may comprise silicon and may be referred to as a device layer or an active layer. Further, in some embodiments, substrate 14 may include one or more epitaxial layers. Substrate 14 may include an active area in which active devices, may be subsequently formed. In some embodiments, semiconductor material 14 may be formed on a substrate comprised of the same or a different material. In one example, semiconductor material 14 is silicon which is epitaxially grown on a silicon substrate. It should be understood that a substrate may mean a semiconductor material, one or more epitaxial layers formed on a semiconductor material, a semiconductor material disposed on an insulating material, or the like. Accordingly, substrate 14 may also be referred to as a semiconductor substrate. Active devices may be formed in active regions 20 and 21 using conventional complementary metal oxide semiconductor (“CMOS”), bipolar, or bipolar-CMOS (“BiCMOS”) processes.

In some embodiments, the depth or thickness of dielectric platform 18 may range from about 1 μm to about 100 μm and the width of dielectric platform 18 may be measured from top surface 16 of substrate 14 to a lower boundary or surface 90 of dielectric platform 18. In some embodiments, lower surface 90 of dielectric platform 18 is parallel to, or substantially parallel to top surface 16 of substrate 14. In some embodiments, lower surface 90 of dielectric platform 18 is at a distance of at least about 1 μm or greater below top surface 16 and the width of dielectric platform 18 is at least about 3 μm or greater. In other embodiments, lower surface 90 of dielectric platform 18 is at a distance of at least about 3 μm or greater below top surface 16 and the width of dielectric platform 18 is at least about 5 μm or greater. In one example, the thickness of dielectric platform 18 may be about 10 μm and the width of dielectric platform 18 may be about 10 μm. In yet other embodiments, it may be desirable that the thickness of dielectric platform 18 be equal to, or approximately equal to, the thickness of substrate 14, for example, the thickness of the semiconductor die and the width of dielectric platform 18 may be up to about 100 μm. The thickness and width of dielectric platform 18 may be varied depending on the application for dielectric platform 18 and the desired die size of the resulting semiconductor device that uses substrate 14. For example, a relatively thicker dielectric platform may be desired in applications where dielectric platform 18 is used to form high Q passive devices compared to an application where dielectric platform 18 is used for isolation.

In one or more embodiments, dielectric platform 18 is capable of isolating one or more transistor types from one or more other transistor types, and/or to isolate different regions of substrate 14 including surrounding and/or enclosing one or more areas of substrate 14. For example, in one or more embodiments, dielectric platform 18 may have a ring or annular type shape capable of enclosing or at least partially enclosing an area or region within the ring, to isolate the inner region of the ring from the outer region of the ring. In such an embodiment, active region 20 may be disposed within the interior of the ring formed by dielectric platform 18 to be physically and/or electrically isolated from another active region 21 disposed exterior to the ring formed by dielectric platform 18. Likewise, dielectric platform 18 may comprise other various shapes and/or forms to provide isolation between two or more adjacent regions of substrate 14, and the scope of the claimed subject matter is not limited in this respect.

The combination of hanging dielectric structures 70, dielectric material 71, and cavity 64A reduces the overall permittivity of dielectric platform 18 so that dielectric platform 18 has a relatively low dielectric constant. In other words, hanging dielectric structures 70, dielectric material 71, and sealed cavity 64A together reduce the dielectric constant of dielectric platform 18. To minimize the dielectric constant of dielectric platform 18, it is desirable to increase the depth of dielectric platform 18, increase the volume of sealed cavity 64A, and reduce the extent of semiconductor material 14 contained in hanging structures 60 (FIG. 4). In some embodiments, a dielectric constant of at least about 1.5 or lower may be achieved by increasing the volume of cavity 64A. The dielectric constant of dielectric platform 18 is reduced compared to, for example, what would be provided by a dielectric platform that has no cavities, openings, or voids. The dielectric constant of dielectric platform 18 may also be reduced by increasing the volume of dielectric material in hanging structures 60 (FIG. 4). Since empty space has the lowest dielectric constant (the dielectric constant of empty space is 1), the more empty space or void space incorporated into the dielectric platform, the lower the overall dielectric constant. Accordingly, increasing the volume of sealed cavities 64A relative to the volume of hanging structures 60 (FIG. 4) is more effective in decreasing the dielectric constant of dielectric platform 18 compared to increasing the volume of dielectric material in hanging dielectric structures 70 (FIGS. 1, 6, and 7).

Additionally, less stress is induced in substrate 14 by dielectric platform 18 compared to a solid or filled dielectric structure, because dielectric platform 18 includes substantial volumes that are not occupied by solids having coefficients of thermal expansion that differ from that of substrate 14. A solid or filled dielectric structure (not shown) that includes, for example, an oxide material with no cavities may generate stress in an adjacent silicon region during heating and cooling of the dielectric structure and the silicon region due to the coefficient of thermal expansion (“CTE”) mismatch between silicon and oxide. Accordingly, the stress on the silicon lattice may lead to defects or dislocations in the silicon region. The dislocations may lead to undesirable excessive leakage currents in active devices formed in the active region, and therefore, forming a dielectric structure such as dielectric platform 18 which has sealed cavity 64A, can reduce or prevent the formation of dislocations in the adjacent active regions, such as active regions 20 and 21, since sealed cavity 64A can provide stress relief. Furthermore, less stress is generated in the formation of dielectric platform 18 compared to a solid or substantially solid dielectric structure in which the solid or substantially solid regions are formed by oxidation because, for example, in silicon, oxidation is accompanied by a 2.2 times (“2.2×”) volume increase.

Silicon dioxide has a dielectric constant of about 3.9. Accordingly, a solid or filled dielectric structure that includes no cavities and includes silicon dioxide may have a dielectric constant of about 3.9. As discussed above, empty space has a lower dielectric constant (the dielectric constant of empty space is 1), thus the more empty space or void space incorporated into the dielectric platform, the lower the overall dielectric constant.

In some embodiments described herein, dielectric platform 18 includes one or more cavities occupying in excess of 40% of the total volume of dielectric platform 18. This may result in an effective dielectric constant reduction of about 30% or greater, from a dielectric constant of about 3.9 to an effective dielectric constant of about 2.74. In one embodiment, dielectric platform 18 includes one or more voids occupying in excess of 50% of the total volume. This may result in an effective dielectric constant reduction of about 39%, from a dielectric constant of about 3.9 to an effective dielectric constant of about 2.39. Increasing the volume of air or empty space in dielectric platform 18 may result in dielectric platform 18 having a dielectric constant of about 1.5 or less. As a result, passive elements formed over dielectric platform 18 have reduced parasitic capacitances to substrate 14 and reduced substrate lossy currents for an inductor. The parasitic substrate capacitance is reduced by both the reduced effective dielectric constant of dielectric platform 18 and the increased thickness of dielectric platform 18.

In addition, dielectric platform 18 may be used to increase the frequency of operation of any devices formed using semiconductor structure 100. For example, passive components such as, for example, inductors, capacitors, or electrical interconnects, may be formed over embedded dielectric platform 18 and may have reduced parasitic capacitive and inductive coupling between these passive components and substrate 14 since embedded dielectric platform 18 has a relatively low dielectric constant or permittivity and since embedded dielectric platform 18 increases the distance between the passive components and the conductive substrate. Passive components may also be referred to as passive devices. Reducing parasitic substrate capacitances may increase the frequency of operation of any devices formed using a dielectric platform. As an example, the passive component may comprise electrically conductive material 24, wherein electrically conductive material 24 may comprise, for example, aluminum, copper, doped polycrystalline silicon, gold, nickel, or permalloy. In various examples, the passive component may be an inductor, a capacitor, a resistor, an electrical interconnect, or a combination thereof and may be coupled to one or more active devices formed in active regions 20 and 21.

At least a portion of dielectric platform 18 may be formed below a top surface 16 of substrate 14. In some embodiments, a majority of dielectric platform 18 is below top surface 16 of substrate 14. In other embodiments, all of, or substantially all of, dielectric platform 18 is below top surface 16 of substrate 14. Since at least a portion of dielectric platform 18 is formed in and below the surface of substrate 14, dielectric platform 18 may be referred to as an embedded dielectric structure. Embedded may mean that at least a portion of dielectric platform 18 is below a plane (not shown) that is coplanar to, or substantially coplanar to, top surface 16 of substrate 14. In some embodiments, the portion of dielectric layer 18 below the plane extends from the plane to a depth of at least about 3 μm or more below the plane and the portion of dielectric platform 18 below the plane has a width of at least about 5 μm or more. In other words, at least a portion of dielectric platform 18 is embedded in substrate 14 and extends a distance of at least about 3 μm or more from top surface 16 toward the bottom surface of substrate 14 and the portion of dielectric platform 18 embedded in substrate 14 has a width of at least about 5 μm or more in some embodiments.

Further, dielectric platform 18 may be used to form relatively high quality passive devices such as, for example, capacitors and inductors having a relatively high Q since dielectric platform 18 may be used to isolate and separate the passive devices from substrate 14. Active devices, such as transistors or diodes, may be formed in regions adjacent to, or abutting, dielectric platform 18, and these active devices may be coupled to passive components such as spiral inductors, interconnects, microstrip transmission lines and the like that are formed on a planar upper surface of dielectric platform 18. Increasing the distance between the passive components and silicon substrate 14 allows higher Qs to be realized for these passive components.

As an example, a field effect transistor (“FET”) 79 may be formed in active region 20 and a FET 89 may be formed in active region 21. FET 79 may be a MOSFET and may include a source region 80 in a portion of substrate 14, a drain region 82 in a portion of substrate 14, a gate oxide 84 over a portion of substrate 14, a gate 86 over gate oxide 84, and a channel region 88 formed in a portion of substrate 14 under gate oxide 84 and between source and drain regions 80 and 82, respectively. FET 89 may be a MOSFET and may include a source region 90 in a portion of substrate 14, a drain region 92 in a portion of substrate 14, a gate oxide 94 over a portion of substrate 14, a gate 96 over gate oxide 94, and a channel region 98 formed in a portion of substrate 14 under gate oxide 94 and between source and drain regions 90 and 92, respectively. The source, drain, and channel regions of a FET can be formed by forming a doped region in semiconductor substrate 14 and therefore the source, drain and channel regions of a FET may be referred to as doped regions.

As discussed above, substrate 14 may comprise a semiconductor material such as, for example, silicon. Substrate 14 may serve as part of a drain region of a vertical transistor formed in active region 21. In this example, a source contact or electrode (not shown) may be formed on or adjacent to an upper surface of substrate 14 and a drain electrode (not shown) may be formed on or adjacent to a lower surface of substrate 14. During operation, the electrical current flows from the source electrode to the drain electrode in the vertical transistor may be substantially perpendicular to the upper and lower surfaces of semiconductor structure 100. In other words, current flows essentially vertically through the vertical transistor from the electrode located adjacent to a top surface of semiconductor structure 100 to a drain electrode located adjacent to the opposite bottom surface of semiconductor structure 100. An example of a vertical transistor is described in United States (“US”) patent application having application Ser. No. 10/557,135, titled “POWER SEMICONDUCTOR DEVICE AND METHOD THEREFOR,” filed Nov. 17, 2005, which claims priority to Patent Cooperation Treaty (“PCT”) International Application Number PCT/US2005/000205 titled “POWER SEMICONDUCTOR DEVICE AND METHOD THEREFOR,” having an International Filing Date of Jan. 6, 2005, and an International Publication Date of Jul. 28, 2005, the contents of both of these patent applications are incorporated herein by reference in their entirety.

Power transistors having relatively high breakdown voltages, and consequently relatively high output power, may be realized by forming a vertical transistor in an active area adjacent to dielectric platform 18, as dielectric platform 18 may provide edge termination for the equipotential lines from an electric field in an active area that is adjacent to dielectric platform 18. Higher breakdown voltages may be achieved as the edge termination provided by dielectric platform 18 may reduce curvature of the equipotential lines. As is generally understood, curvature of the equipotential lines results in lower breakdown voltages. To maximize breakdown voltage, the equipotential lines are parallel, or substantially parallel, to top surface 16 of substrate 14, and these equipotential lines are planar with little to no curvature.

If relatively high breakdown voltages are desired, then the lateral sidewall of dielectric platform 18 that contacts the active region is formed to be a dielectric material that is perpendicular, or substantially perpendicular, relative to top surface 16 of substrate 14 to allow the equipotential lines to terminate in a substantially perpendicular orientation at the lateral sidewall of dielectric platform 18. If the lateral sidewall of dielectric platform 18 is angled relative to top surface 16 of substrate 14, then this may not reduce curvature of the equipotential lines as desired, and therefore, dielectric termination structure 26 that includes trench 54 and oxide layer 55 may be included to provide a perpendicular, or substantially perpendicular, dielectric sidewall structure to provide edge termination.

It should be noted that including dielectric termination structure 26 is optional. Termination structure 26 may also be referred to as a dielectric structure. Termination structure 26 may be desirable in applications where high voltage and/or high power is desired and where the lateral boundaries of dielectric platform 18 do not include a sidewall that is substantially perpendicular to top surface 16 of substrate 14. For example, referring to FIG. 1, the lateral sidewall 73 of dielectric region 71 is angled, and not perpendicular, to top surface 16 of substrate 14. Accordingly, termination structure 26 may be included to provide a dielectric sidewall 57 that is perpendicular to, or substantially perpendicular to, top surface 16.

Dielectric termination structure 26 may be adjacent to, abutting, and/or surrounding, active regions 20 and 21 to provide edge termination for terminating equipotential lines in active regions 20 and 21, which may result in relatively higher breakdown voltages for active devices formed in the active regions.

Similarly, in embodiments where termination structure 26 is omitted, dielectric platform 18 may be adjacent to, abutting, and/or surrounding, active regions 20 and 21 to provide edge termination for terminating equipotential lines in the active regions, which may result in relatively higher breakdown voltages for some kinds of active devices such as, for example, vertical transistors, formed in the active regions. In addition, if dielectric platform 18 surrounds one or more active regions, then dielectric platform 18 may also be used to provide electrical isolation. For example, dielectric platform 18 may be used to electrically isolate active regions from each other, which may also result in electrical isolation between any active devices formed in the isolated active regions.

Although only a single active device is discussed as being formed in each of active regions 20 and 21, the methods and apparatuses described herein are not limited in this regard. In some embodiments, a plurality of active devices may be formed in active regions 20 and 21. Other types of devices that may be formed in active regions 20 and 21 include bipolar junction transistors, junction field effect transistors, insulated gate bipolar junction transistors, diodes, thyristors, passive devices, or the like.

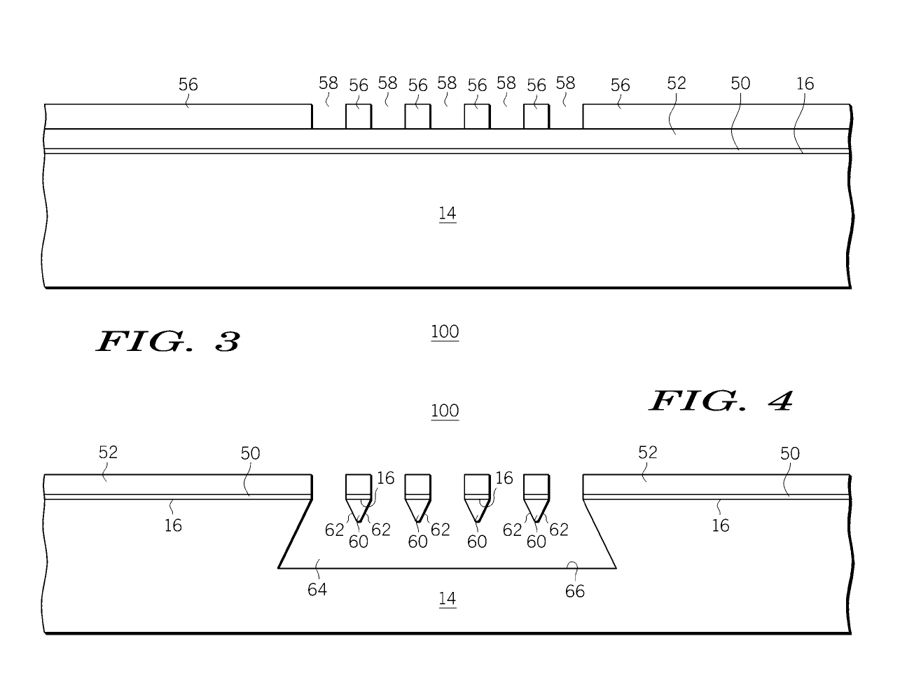

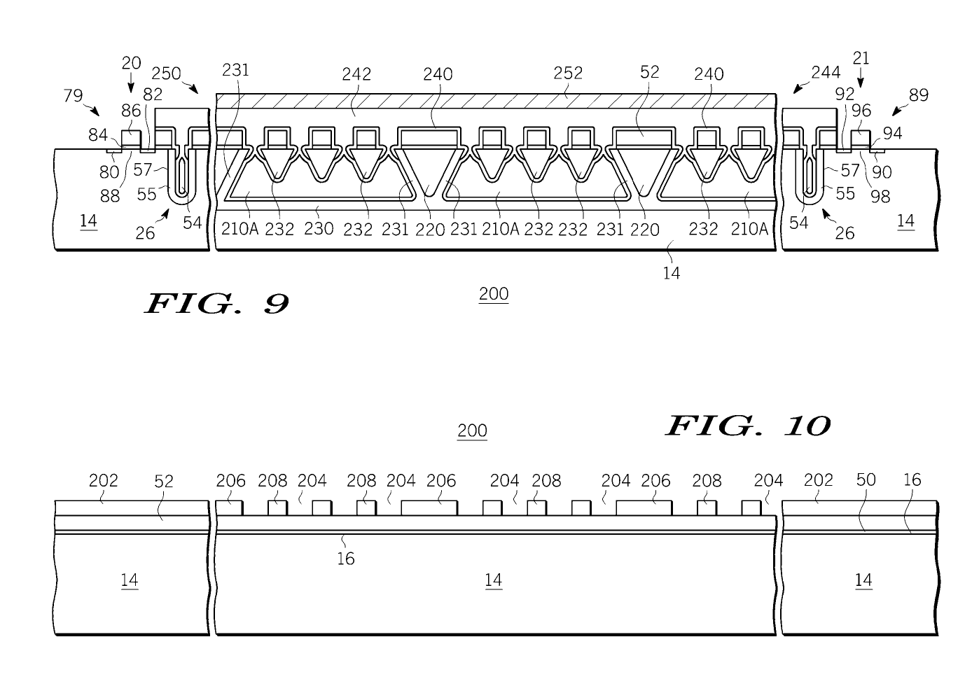

FIG. 2 is a cross-sectional view of a semiconductor structure at a beginning stage of manufacture. What is shown in FIG. 2 is semiconductor substrate 14, which may be used as a substrate for the fabrication of semiconductor structures 100 (FIG. 1), 200 (FIG. 9), and 300 (FIG. 15). Substrate 14 may comprise a semiconductor material such as, for example, silicon, and may be doped or undoped depending on the application, although the methods and apparatuses described herein are not limited in this regard. Substrate 14 may have a thickness ranging from about 100 μm to about 1,000 μm. However, the thickness of substrate 14 may be reduced through subsequent thinning processes in some embodiments.

A layer of dielectric material 50 is formed on substrate 14. Layer 50 comprises, for example, silicon dioxide (“SiO₂”) and may have a thickness ranging from about 50 Å to about 1000 Å. Dielectric layer 50 may be formed using deposition techniques or thermal growth techniques such as, for example, thermal oxidation of silicon.

A layer of dielectric material 52 is formed on dielectric layer 50. Layer 52 comprises, for example, silicon nitride (“Si₃N₄”) and may have a thickness ranging from about 100 Å to about 2,000 Å. In some embodiments, dielectric layer 52 has a thickness that is about two times (“2×”) greater than the thickness of dielectric layer 50. Dielectric layer 52 may be formed using low pressure chemical vapor deposition (“LPCVD”).

Dielectric layer 52 may be useful as an etch stop, a protective layer, and/or a mask layer during the processing of structure 100. Dielectric layer 50 is between substrate 14 and silicon nitride layer 52 to prevent damage that may result from forming silicon nitride layer 52 directly on substrate 14. An advantage of forming dielectric layer 52 as silicon nitride and dielectric layer 50 as silicon dioxide is that the silicon nitride serves as an oxidation barrier during subsequent oxidation steps.

Dielectric layer 52 or a combination of dielectric layer 50 and dielectric layer 52 may serve as a hard mask, and may be referred to as a masking layer. Since the photoresist over dielectric layer 52 is also etched as part of the silicon etch used to etch portions of substrate 14, dielectric layer 52 or a combination of dielectric layer 50 and dielectric layer 52 may be used as a hard mask to prevent the undesired etching of the upper surface of substrate 14 during the formation of cavity 64 (FIG. 4).

Referring now to FIG. 3, a layer of photoresist is dispensed on silicon nitride layer 52. The layer of photoresist is patterned to form a masking structure 56 having openings 58 that expose portions of silicon nitride layer 52. In some embodiments, openings 58 have a width ranging from about 0.5 micron to about one micron, and openings 58 are spaced apart from each other by a distance of about 0.5 micron to about one micron, although the methods and apparatuses described herein are not limited in this regard. Photolithography processes or operations involve the use of masks and may sometimes be referred to as masking operations or acts.

FIG. 4 is a cross-sectional side view of the structure of FIG. 3 at a later stage of manufacture in accordance with an embodiment of the present invention. FIG. 5 is a top view of the structure of FIG. 4 in accordance with an embodiment of the present invention, and FIG. 4 is a cross-sectional view taken along section line 4-4 of FIG. 5. Layers 50 and 52 are not shown in FIG. 5 to illustrate the formation of structures 60 in substrate 14. With reference to FIGS. 4 and 5, the exposed portions of silicon nitride layer 52 and the portions of silicon dioxide layer 50 and substrate 14 that are below the exposed portions of silicon nitride layer 52 are removed by, for example, etching, to form a cavity 64 having a floor 66 and containing a plurality of structures 60 having sidewalls 62. Therefore, in some embodiments, structures 60 and cavity 64 may be formed simultaneously by etching substrate 14. Masking structure 56 (FIG. 3) is stripped or removed after the removal of portions of layer 52, layer 50, and substrate 14.

Structures 60 extend from top surface 16 into cavity 64. The lower portions of structures 60 are vertically spaced apart or vertically separated from floor 66 and are therefore referred to as hanging partitions, hanging pillars, hanging columns, hanging walls, hanging structures, or suspended structures. In embodiments in which suspended or hanging structures 60 are comprised of silicon, they may be referred to as silicon hanging structures. Although structures 60 are described and shown as hanging structures herein, the methods and apparatuses described herein are not limited in this regard. Although not shown, as mentioned above, in other embodiments, hanging structures 60 may be hanging walls such as, for example, elongated hanging walls. Cavity 64 is also referred to as an opening.

In some embodiments, cavity 64 may be formed using at least one etch operation to remove portions of layers 50 and 52, and substrate 14. In other embodiments, two or three etching operations may be used to form cavity 64. For example, one etch operation may be used to remove portions of substrate 14 and layers 50 and 52. As another example, three etch operations may be used to remove portions of layer 52, layer 50, and substrate 14, respectively.

Silicon nitride layer 52 may be etched using a wet chemical etch or a dry etch process such as, for example, a reactive ion etch (“RIE”). Silicon dioxide layer 50 may be etched using a wet chemical etch or a dry etch process such as, for example, a reactive ion etch (“RIE”). Next, a portion of substrate 14 may be removed using an etch process.

In some embodiments, the etch chemistry is selected so that sidewalls 62 form an angle that is not perpendicular to top surface 16. For example, hanging structures 60 may be tapered such that the upper portions of hanging structures 60 are wider than the lower portions of hanging structures 60. Thus, the spacing or distance between hanging structures 60 at the upper portions of hanging structures 60 is substantially different than the distance between hanging structures 60 at the lower portions of hanging structures 60. In some embodiments, the distance between the upper portions of hanging structures 60 is substantially smaller, or less than, the distance between the lower portions of hanging structures 60.

As stated above, in some embodiments, the etch chemistry is selected so that sidewalls 62 form an angle that is not perpendicular to top surface 16. In some embodiments, trenches with non-vertical sidewalls are formed using reactive ion etching (“RIE”). Hanging structures 60 may be formed using a series of alternating passivation and etch steps which comprise a passivation step that coats all exposed surfaces and an etch step which preferentially removes the passivation in certain regions and then permits etching of the exposed portions in the unpassivated areas. The passivation/etch cycles are repeated to form hanging structures 60, wherein portions of substrate 14 are removed so that hanging structures 60 are separated from floor 66. As an example, an initial etch of substrate 14 may be performed to form one or more trenches in substrate 14 and then the passivation step may include forming a passivation layer that comprises a polymer (not shown) using a deposition process that forms the passivation layer along the sidewalls and bottoms of the trenches. The etching step may include a dry etch that removes the portions of the passivation layer that are at the bottom and lower portions of the trenches. In other embodiments, one or more of the etch process parameters are varied during the process to achieve a specific sidewall profile. Examples of process parameters that can be varied include pressure, etch cycle time, passivation formation cycle time, the amount of precursor used for passivation, the amount of precursor used for etching, and power.

Hanging structures 60 can be formed by starting with a targeted depth for dielectric platform 18 (FIG. 1), and then determining a critical feature width that will be etched through upon completion of the etch process. A dielectric platform such as, for example, dielectric platform 250 (FIGS. 9 to 15) that has multiple isolated cavities can be formed by laying out a mask to have feature widths larger than the critical width, which will not be etched through, and feature widths that are smaller than the critical width, which will be etched through.

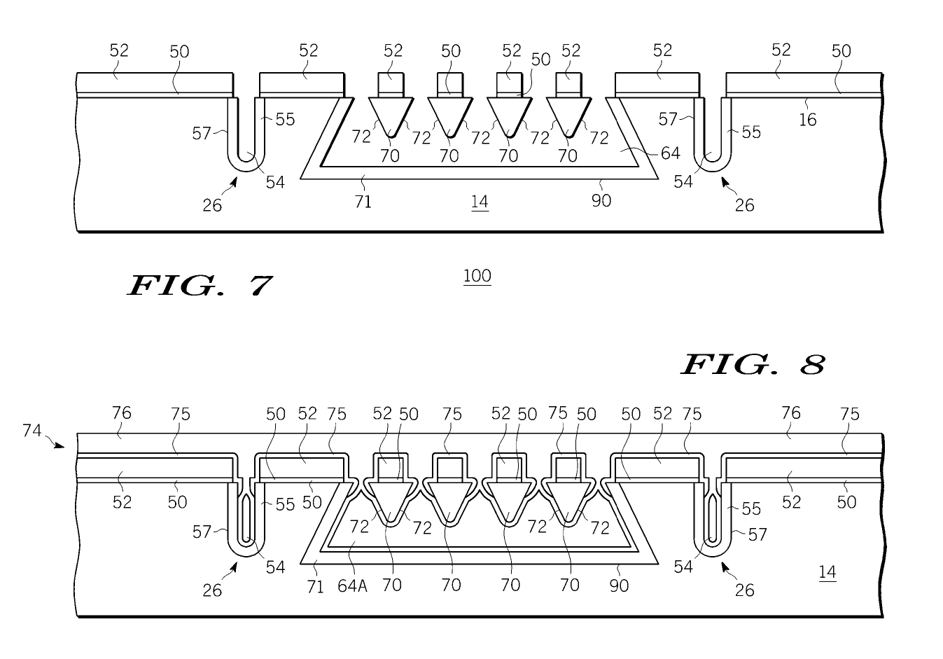

As is discussed below with reference to FIG. 6, thermal oxidation is performed to convert a portion of, all of, or substantially all of, the silicon of hanging structures 60 to silicon dioxide to form silicon dioxide or dielectric hanging structures 70 having sidewalls 72 (FIG. 7). Thus, the thermal oxidation modifies or alters silicon hanging structure 60 so that they become silicon dioxide hanging structures 70. Accordingly, structures 70 may be referred to as modified or altered hanging structures, or in some embodiments, enlarged hanging structures. After the thermal oxidation, the upper portions of silicon dioxide hanging structures 70 (FIG. 7) are separated from each other and do not contact each other. In some embodiments, the distance between silicon hanging structures 60 ranges from about 0.5 μm to about 2 μm and the widths of the upper portions of silicon hanging structures 60 is about 1.5 μm or less. It should be noted that the thicker the upper portions of silicon hanging structures 60, the longer it will take to oxidize silicon hanging structures 60. The width dimension of silicon hanging structures 60 may be referred to as a diameter depending on the shape of silicon hanging structures 60. In some embodiments, after the thermal oxidation process is performed as is described with reference to FIG. 7 to convert a portion of, all of, or substantially all of, silicon hanging structures 60 from silicon to silicon dioxide, the distance between the upper portions of silicon dioxide hanging structures 70 (FIG. 7) is about 1 μm or less and the distance between the lower portions of silicon dioxide hanging structures 70 (FIG. 7) is about 1.5 μm or greater. The lower portions of silicon dioxide hanging structures 70 are vertically spaced apart or vertically separated from the lower surface of cavity 64. Further, the widths of the lower portions of silicon dioxide hanging structures 70 are substantially smaller than the widths of the upper portions of silicon dioxide hanging structures 70. For example, the widths of the upper portions of silicon dioxide hanging structures 70 may be at least about two times (“2×”) greater than the widths of the lower portions of silicon dioxide hanging structures 70. In other words, the widths of the upper portions of silicon dioxide hanging structures 70 may be more than about two times (“2×”) the widths of the lower portions of silicon dioxide hanging structures 70 in some embodiments. For example, if the widths of the upper portions of silicon dioxide hanging structures 70 is about 1.5 μm, then the widths of the lower portions of silicon dioxide hanging structures 70 is about 0.75 μm or less. In some embodiments, the widths of the upper portions of silicon dioxide hanging structures 70 may be about four times (“4×”) the widths of the lower portions of silicon dioxide hanging structures 70, although the methods and apparatuses described herein are not limited in this regard. As may be appreciated, decreasing the widths at the lower portions of silicon dioxide hanging structures 70 will further increase the amount of empty space in dielectric platform 18 which will result in a dielectric platform with a relatively lower effective dielectric constant. The oxidation also converts a portion of substrate 14 which is exposed between adjacent structures 60 and the exposed edges or sidewalls of cavity 64 to silicon dioxide to form dielectric layer 71 (FIG. 6).

Although a square shaped cavity 64 is illustrated in FIGS. 4 and 5, this is not a limitation of the present invention. Cavity 64 can have other shapes including a polygonal shape, a circular shape, or the like. In other embodiments, dielectric platform 18 may be formed to surround a portion of substrate 14. Accordingly, cavity 64 may be formed surrounding a portion of substrate 14. This may be desirable to isolate one portion of substrate 14 from another portion of substrate 14 using dielectric platform 18.

FIG. 6 is a cross-sectional view of a semiconductor structure 100 at a later stage of manufacture. A thermal oxidation process is performed so that the exposed silicon of structure 100 is converted to silicon dioxide, thereby forming a silicon dioxide layer or region 71 which may include silicon dioxide hanging structures 70. In particular, the silicon of silicon hanging structures 60 (FIG. 4) may be partially, or in the embodiment illustrated in FIG. 6, completely converted to silicon dioxide to form silicon dioxide hanging structures 70. In other words, the silicon between sidewalls 62 (FIG. 4) of silicon hanging structures 60 may be substantially converted to silicon dioxide in some embodiments. In addition, as shown in FIG. 6 during the thermal oxidation process, the bottom of cavity 64, that is floor 66 (FIG. 4), is also converted to silicon dioxide to form silicon dioxide layer or region 71. Since the dielectric constant of silicon is greater than the dielectric constant of silicon dioxide, reducing the amount of silicon in hanging structure 70 will reduce the effective dielectric constant of dielectric platform 18.

As is well known, about 2.2 units of silicon dioxide is formed from about one unit of silicon during thermal oxidation. In other words, about 2.2 Å of thermal oxide may be formed from about 1 Å of silicon. As a result, the formation of silicon dioxide during the thermal oxidation process illustrated with reference to FIG. 6 has the effect of decreasing the spacing between silicon hanging structures 60 (FIG. 4) during the thermal oxidation process and increasing the size of the hanging structures. Thus, the spacing between the resulting silicon dioxide hanging structures 70 is less than the spacing between silicon hanging structures 60 (FIG. 4) and hanging structures 70 are larger than hanging structures 60.

As may be appreciated, subsequent capping of cavity 64 may be facilitated by the thermal oxidation process and the initial shape of silicon hanging structures 60 (FIG. 4), wherein the upper portions of silicon hanging structures 60 are spaced closer to each other compared to the lower portions of silicon hanging structures 60. In particular, the spacing between the upper portions of silicon hanging structures 60 (FIG. 4) is decreased to a distance that will facilitate capping or sealing of cavity 64 using, for example, a non-conformal dielectric material. In addition, the effective dielectric constant of the resulting dielectric platform 18 is reduced due to the initial shape of silicon hanging structures 60 (FIG. 4), as the shape of silicon hanging structures 60 allows for increasing the amount of empty space in dielectric platform 18. In other words, the shape of silicon hanging structures 60 allows for decreasing the amount of silicon or silicon dioxide material in dielectric platform 18.

Although the thickness or the amount of the silicon dioxide of silicon dioxide hanging structures 70 is limited after all of the silicon of silicon hanging structures 60 is consumed during the thermal oxidation process, the thermal oxidation process may continue longer to increase the thickness of the silicon dioxide at the lateral and lower boundaries of dielectric platform 18. In other words, the oxidation process may continue longer to increase the amount of silicon dioxide at the bottom of cavity 64 and along the lateral perimeter of cavity 64.

FIG. 7 is a cross-sectional view of semiconductor structure 100 at a later stage of fabrication. After the oxidation process is performed, termination structure 26 may be formed. Silicon nitride layer 52, silicon oxide layer 50, and semiconductor material 14 may be patterned using photolithography and etching processes. The photolithography and etching may include forming a layer of a radiation-sensitive material, such as photoresist (not shown), over structure 100 at the stage of manufacture illustrated in FIG. 6, exposing the photoresist using, for example, ultraviolet (“UV”) radiation to form a mask, and then etching portions of layer 52, layer 50, and semiconductor material 14 using an anisotropic etch process such as, for example, a reactive ion etch (“RIE”), to form a trench 54 that surrounds dielectric platform 18. Trench 54 may also be referred to as a cavity, an opening, a void, a gap, an empty region, an empty space, or the like.

After trench 54 is formed, the photoresist mask (not shown) over structure 100 used to form trench 54 is stripped or removed. Next, a dielectric layer 55 is formed along the sidewall of trench 54. Dielectric layer 55 has an exterior sidewall 57. Trench 54, dielectric layer 55, and sidewall 57 form a dielectric termination structure 26 as is discussed above. In some embodiments, dielectric layer 55 is an oxide layer such as silicon dioxide having a thickness ranging from about 50 Å to about 5,000 Å. Oxide layer 55 may be formed using deposition techniques or thermal growth techniques such as, for example, thermal oxidation of silicon.

If a thermal oxidation process is used to form oxide layer 55, then other portions of structure 100 may also be affected by the oxidation. For example, the amount of silicon dioxide at the bottom of cavity 64 and along the lateral perimeter of cavity 64 may be increased as part of this thermal oxidation. Further, in alternate embodiments, hanging structures 60 may be partially oxidized during the initial thermal oxidation described with reference to FIG. 6 so that hanging structures 60 comprise silicon and silicon dioxide and then part of, or all of, the remaining silicon in hanging structures 60 may be further converted to silicon dioxide using the subsequent thermal oxidation process that is used to form oxide layer 55. Accordingly, the thickness of oxide layer 55 and the amount of silicon dioxide at the bottom of cavity 64, along the lateral perimeter of cavity 64, and in hanging structures 70 may be controlled by varying the timing of the two thermal oxidation processes used to form silicon dioxide hanging structures 70 and oxide layer 55.

Although termination structure 26 has been described above as being formed after the formation of cavity 64, this is not a limitation of the present invention. In other embodiments, termination structure 26 may be formed prior to the formation of cavity 64.

Referring now to FIG. 8, a non-conformal layer of dielectric material 75 is formed on layer 52. Layer 75 may be an oxide, phosphosilicate glass (PSG), borophosphosilicate glass (“BPSG”), borosilicate glass (“BSG”), silicon nitride, or silicon oxynitride. As discussed with reference to FIG. 1, dielectric layer 75 decreases the distance between dielectric hanging structures 70, thereby reducing the openings between dielectric hanging structures 70. A portion of layer 75 may enter cavity 64 and become deposited on portions of sidewalls 72 and the sidewalls of cavity 64. In some embodiments, layer 75 does not fill cavity 64. Similarly, layer 75 does not fill trenches 54.

A layer of dielectric material 76 is formed on layer 75 and along sidewalls of cavity 64. Layer 76 may be a conformal layer that seals cavity 64 and trenches 54. In some embodiments, layer 76 may hermetically seal cavity 64 and trenches 54. The sealed cavity is identified by reference character 64A. Thus, layer 76 is referred to as a sealing layer. In other words, conformal layer 76 may fill any openings or cracks in layer 75, and in general prevent the propagation of gases or moisture into sealed cavity 64A. By way of example, sealing layer 76 is silicon nitride (“Si₃N₄”). In other embodiments, sealing layer 76 may be LPCVD low temperature oxide (LTO), LPCVD high temperature oxide (HTO), LPCVD TEOS, or LPCVD PSG. Layer 75 in combination with sealing layer 76 form capping structure 74. Capping structure 74 may have a thickness ranging from about 1,000 Å to about 4 μm. In some embodiments, due to the relatively small openings between the upper portions of dielectric hanging structures 70, capping structure 74 may enter into a portion of cavity 64 or a region between the upper portions of adjacent dielectric hanging structures 70, but not fill cavity 64 due in part to the relatively small size of the openings between the upper portions of dielectric hanging structures 70. Similarly, in some embodiments, capping structure 74 may enter into a portion of trenches 54 but not fill trenches 54.

In accordance with another embodiment, layer 75 comprises a layer of polysilicon that may be deposited using, for example, an LPCVD technique followed by oxidation of the polysilicon. Then sealing layer 76 is formed on layer 75. In some embodiments, capping structure 74 is a single layer of material that comprises either a conformal or non-conformal layer of material. Suitable materials for capping structure 74 include dielectric materials such as LPCVD deposited tetraethylorthosilicate (“TEOS”), LPCVD deposited oxide, LPCVD deposited nitride, LPCVD deposited low stress nitride, a polymeric material, or the like.

In some embodiments, capping structure 74 may be planarized using, for example, a Chemical mechanical Planarization (“CMP”) technique.

Accordingly, the capping or sealing of cavities 64 may be accomplished by forming a non-conformal material followed by a conformal material. In this example, the non-conformal layer such as, for example, layer 75 may enter into a portion of sealed cavity 64A or a region between the upper portions of adjacent dielectric hanging structures 70, but not fill sealed cavity 64A due in part to the relatively small size of the openings between the upper portions of dielectric hanging structures 70 since layer 75 is a non-conformal layer. Then a conformal material such as, for example, sealing layer 76 may be formed on layer 75.

In some embodiments, cavity 64 is evacuated to a pressure less than atmospheric pressure. In other words, the pressure in sealed cavity 64A is below atmospheric pressure. As an example, the pressure in sealed cavity 64A may range from about 0.1 Torr to about 700 Torr. In one example, the pressure in sealed cavity 64A is about 10 Torr. The type of substance or material within sealed cavity 64A is not a limitation of the present invention. For example sealed cavity 64A may contain a solid matter or a fluid such as a gas or a liquid.

Referring back to FIG. 1, the portions of capping structure 74, silicon nitride layer 52 and silicon dioxide layer 50 in active regions 20 and 21 are removed after the formation of dielectric platform 18. Active and passive semiconductor devices may be formed in or from the portions of substrate 14 adjacent dielectric platform 18. In addition, active or passive circuit elements, or portions thereof, may be formed on dielectric platform 18. By way of example, a passive circuit element 24 is formed on dielectric platform 18.

Although dielectric platform 18 is described as having a sealed cavity 64A, the methods and apparatuses described herein are not limited in this regard. For example, in alternate embodiments, sealed cavity 64A could be filled with a material, such as, for example, a material comprising an oxide, nitride, or silicon if so desired, to form a solid or filled dielectric platform (not shown) that is devoid of any cavities. Such a solid filled dielectric platform would have a relatively higher dielectric constant compared to an air-gap dielectric platform such as dielectric platform 18 since the material used to fill sealed cavity 64A would have a higher dielectric constant compared to an opening or void. Examples of materials that may be used to fill, or backfill, sealed cavity 64A may include silicon nitride, polycrystalline silicon, or an oxide material formed using, for example, a hot wall TEOS process.

FIG. 9 is a cross-sectional view of a semiconductor structure 200 in accordance with another embodiment of the present invention that illustrates a dielectric platform (“DP”) 250, active regions 20 and 21, and an electrically conductive material 252. Dielectric platform 250 may be referred to as a dielectric structure or a dielectric region, and active regions 20 and 21 may also be referred to as active areas, active area regions or portions of active areas since active devices, or portions of active devices are formed in active regions 20 and 21.

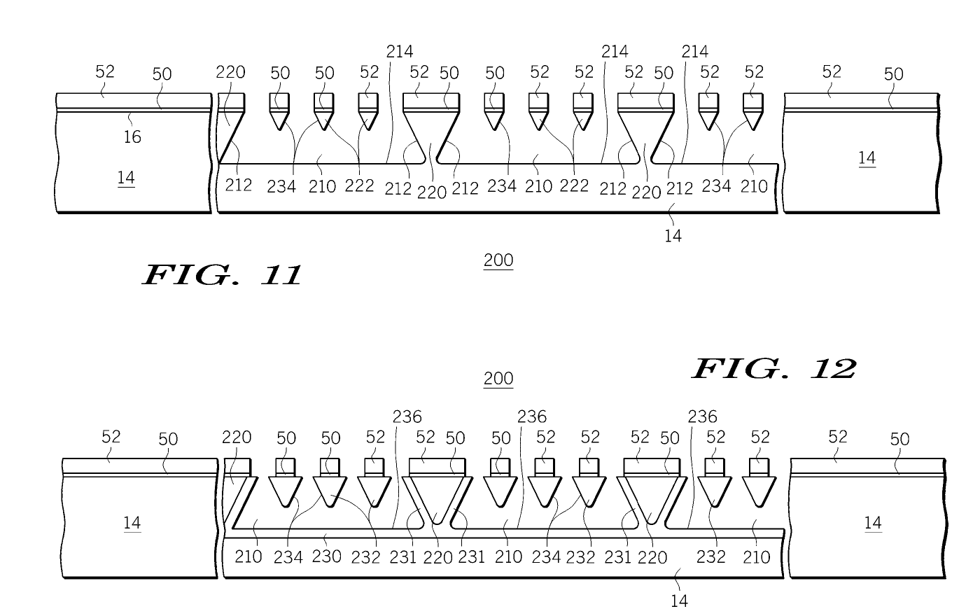

Dielectric platform 250 of semiconductor structure 200 comprises a plurality of sealed cavities 210A, support structures 220, and dielectric hanging structures 232 formed in substrate 14. Substrate 14 has been described with reference to FIG. 1. Support structures 220 are spaced apart from each other by sealed cavities 210A. Sealed cavities 210A may be hermetically sealed under vacuum. However, air or another fluid may be within sealed cavities 210A. A capping structure 244 (FIG. 14) is formed over dielectric hanging structures 232 and cavities 210 (FIGS. 11-13) to form sealed cavities 210A. When sealed, the cavities are identified by reference character 210A and may be referred to as sealed voids, sealed air gaps, sealed cavities, closed cells, or closed cell voids. The dimensions and advantages of a dielectric platform such as dielectric platform 250 have been described with reference to dielectric platform 18.

Active regions 20 and 21 and FETs 79 and 89 have been described with reference to FIG. 1. It should be noted that ellipses have been used in FIGS. 9-14 to further illustrate that the number of sealed cavities 210A, the number of hanging dielectric structures 232 within a sealed cavity 210A, and the number of support structures 220 are not limitations of the present invention.

Support structures 220 and/or projections 231 serve as support structures that may used to increase the structural integrity of dielectric structure 250. In addition, support structures 220 and/or projections 231 may be used as barrier structures to form multiple cavities 210A that are physically isolated from each other. Accordingly, if capping structure 244, structures 220 or 231 experience a rupture or fracture, this rupture or fracture is contained in a limited area so that any contamination external to the dielectric platform 250 that propagates into cavities 210A through the rupture or fracture may be contained in a limited area of dielectric platform 250 due to the physical isolation of the multiple cavities from each other. For example, a closed cell configuration would prevent a fracture or rupture from introducing ambient gas into all of the multiple cavities of dielectric platform 250. The multiple isolated cavities 210A may be referred to as compartments.

FIG. 10 is a cross-sectional view of semiconductor structure 200 at an early stage of manufacture in accordance with an embodiment of the present invention. Semiconductor structure 200 comprises dielectric layer 52 on dielectric layer 50 which is formed on or from substrate 14. Substrate 14, dielectric layers 50 and 52, and the formation of dielectric layers 50 and 52 over substrate 14 have been described with reference to FIG. 2. A layer of photoresist (not shown) is dispensed on silicon nitride layer 52. The layer of photoresist is patterned to form a masking structure 202 having openings 204 that expose portions of silicon nitride layer 52. Masking structure 202 comprises masking elements 206 and 208, wherein the widths of masking elements 206 are greater than the widths of masking elements 208.

FIG. 11 is a cross-sectional view of the structure of FIG. 10 at a later stage of manufacture in accordance with an embodiment of the present invention. With reference to FIG. 11, the exposed portions of silicon nitride layer 52 and the portions of silicon dioxide layer 50 and substrate 14 that are below the exposed portions of silicon nitride layer 52 are removed by, for example, etching, to form one or more cavities 210 having sidewalls 212 and floors 214. Cavities 210 are also referred to as voids, gaps, air gaps, openings, empty regions, empty space, or the like. Cavities 210 are laterally separated or spaced apart by support structures 220. Support structures 220 are portions of substrate 14 that remain after the formation of cavities 210 and thus extend from floors 214 to top surface 16. Although a plurality of support structures 220 are shown, the present invention is not limited in this regard. For example, a single support structure 220 may be formed. Support structures 220 also serve as barriers between cavities 210 and therefore are also referred to as barriers.

The etch that forms cavities 210 also forms structures 222 that extend from top surface 16 into cavities 210 and have sidewalls 224. The lower portions of structures 222 are vertically spaced apart or vertically separated from floors 214 and are therefore referred to as hanging partitions, hanging pillars, hanging columns, hanging walls, or hanging structures. Typically, hanging structures 222 are comprised of silicon and are referred to as silicon hanging structures 222. In some embodiments, the widths of masking elements 206 and 208 are selected so that portions of substrate 14 protected by masking structures 206 are not completely undercut, whereas the portions of substrate 14 protected by masking structures 208 are completely undercut or etched through. That is, masking element 206 is patterned to have a greater width than masking element 208 so the etch that forms hanging structures 222 undercuts the portions of substrate 14 below masking structures 208 from two sides but does not completely undercut the portions of substrate 14 protected by masking element 206. The etching from one side of a hanging structure meets the etching from the opposing side, leaving hanging structures 222 vertically spaced apart from floors 214. Thus support structures 220 extend from floors 214 to top surface 16 and hanging structures 222 extend from top surface 16 into cavities 210. Although three hanging structures 222 are shown within each cavity 210, this is not a limitation of the present invention. For example, in some embodiments there may be one, two, three, four, or more silicon hanging structures formed within each cavity 210. Likewise, there may be more or fewer than three supports structures 220. Although not shown, in other embodiments, hanging structures 222 may be hanging walls such as, for example, elongated hanging walls.

Turning briefly to FIG. 19, FIG. 19 is a top view of structure 200 at the stage of manufacturing illustrated in FIG. 11 in accordance with an embodiment of the present invention. Layers 50 and 52 are not shown in FIG. 19 to illustrate the formation of structures 222 and 220 in substrate 14. The shape of the region where cavities 210 are formed in the embodiment illustrated in FIG. 19 is not a limitation of the present invention. For example, in other embodiments, cavities 210 may be formed to surround a portion of substrate 14.

Turning back to FIG. 11, It may be desirable for the depth of cavity 210 to be greater than the width of cavity 210. Thus, in some embodiments the depth of cavity 210 may be at least two times (“2×”) greater than the width of cavity 210. Alternatively, the depth of cavity 210 may be at least about ten times (“10×”) greater than the width of cavity 210. For example, if the width of cavity 210 is about two μm, the depth of cavity 210 may be about 20 μm or more. In other embodiments, the width of cavity 210 may be greater than the depth of cavity 210.

FIG. 12 is a cross-sectional view of semiconductor structure 200 at a later stage of manufacture. A thermal oxidation process is performed so that the exposed silicon of structure 200 is converted to silicon dioxide, thereby forming a silicon dioxide layer or region 230 which may include silicon dioxide hanging structures 232. Silicon dioxide region 230 has projections or arms 231. In particular, the silicon of silicon hanging structures 222 (FIG. 11) may be partially, or in the embodiment illustrated in FIG. 12, completely converted to silicon dioxide to form silicon dioxide hanging structures 232 having sidewalls 234. Thus, the oxidation modifies silicon hanging structures 222 so that they become silicon dioxide hanging structures 232. In other words, the silicon between sidewalls 222 (FIG. 11) of silicon hanging structures 222 may be substantially converted to silicon dioxide in some embodiments. In addition, as shown in FIG. 12 during the thermal oxidation process, the bottom of cavity 210, that is floor 214 (FIG. 11), is also converted to silicon dioxide to form silicon dioxide layer or region 230 having a boundary 236. Since the dielectric constant of silicon is greater than the dielectric constant of silicon dioxide, reducing the amount of silicon in structure 232 will reduce the effective dielectric constant of dielectric platform 250.

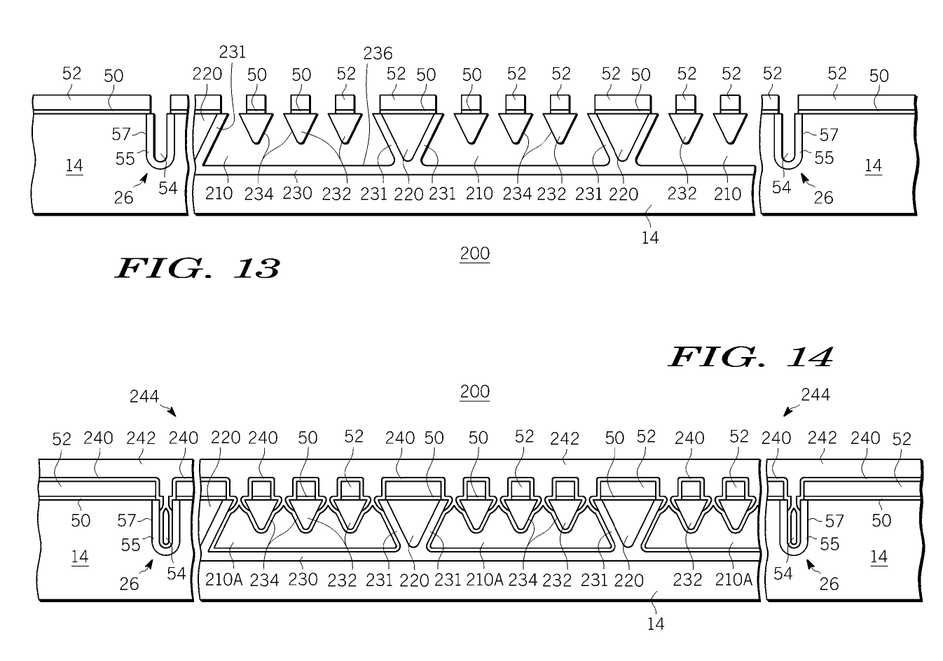

FIG. 13 is a cross-sectional view of semiconductor structure 200 at a later stage of fabrication. After the oxidation process is performed, a trench termination structure 26 may be formed. Techniques for forming trench termination structure 26 have been described with reference to FIG. 7.

Referring now to FIG. 14, a non-conformal layer of dielectric material 240 is formed on or covers layer 52 and portions of sidewalls 234 of dielectric hanging structures 232. Layer 240 may be an oxide, phosphosilicate glass (PSG), borophosphosilicate glass (“BPSG”), borosilicate glass (“BSG”), silicon nitride, or silicon oxynitride. As discussed with reference to FIG. 9, dielectric layer 240 decreases the distance between dielectric hanging structures 232, thereby reducing the openings between dielectric hanging structures 232. A portion of layer 240 may enter cavity 210 and become deposited on portions of sidewalls 234 and the sidewalls of cavities 210. In some embodiments, layer 240 does not fill cavities 210.

A layer of dielectric material 242 is formed on layer 240 and along sidewalls of cavities 210. Layer 242 may be a conformal layer that hermetically seals cavities 210 and trenches 54. The sealed cavities are identified by reference character 210A. Thus, layer 242 is referred to as a sealing layer. In other words, conformal layer 242 may fill any openings or cracks in layer 240, and in general prevent the propagation of gases or moisture into sealed cavities 210A. By way of example, sealing layer 242 is silicon nitride (“Si₃N₄”). In other embodiments, conformal layer 242 may be LPCVD low temperature oxide (LTO), LPCVD high temperature oxide (HTO), LPCVD TEOS, or LPCVD PSG. Layer 240 in combination with sealing layer 242 form capping structure 244 that covers hanging structures 232. Capping structure 244 may have a thickness ranging from about 1,000 Å to about 4 μm. In some embodiments, due to the relatively small openings between the upper portions of dielectric hanging structures 232, layer 240 of capping structure 244 may enter into a portion of one or more cavities 210 or a region between the upper portions of adjacent dielectric hanging structures 232, but not fill the one or more cavities 210 due in part to the relatively small size of the openings between the upper portions of dielectric hanging structures 232. Similarly, in some embodiments, a portion of layer 240 may partially enter trenches 54 but not fill trenches 54.

In accordance with another embodiment, layer 240 comprises a layer of polysilicon that may be deposited using, for example, an LPCVD technique followed by oxidation of the polysilicon. Then sealing layer 244 is formed on layer 240. In some embodiments, capping structure 244 is a single layer of material that comprises either a conformal or non-conformal layer of material. Suitable materials for capping structure 244 include dielectric materials such as LPCVD deposited TEOS, LPCVD deposited oxide, LPCVD deposited nitride, LPCVD deposited low stress nitride, a polymeric material, or the like.

In some embodiments, capping structure 244 may be planarized using, for example, a CMP technique.

Accordingly, the capping or sealing of cavities 210 may be accomplished by forming a non-conformal material followed by a conformal material. In this example, the non-conformal layer such as, for example, layer 240 may enter into portions of sealed cavities 210A or a region between the upper portions of adjacent dielectric hanging structures 232, but not fill sealed cavities 210A due in part to the relatively small size of the openings between the upper portions of dielectric hanging structures 232 since layer 240 is a non-conformal layer. Then a conformal material such as, for example, layer 242 may be formed on layer 240.

In some embodiments, cavities 210 are evacuated to a pressure less than atmospheric pressure. In other words, the pressure in sealed cavities 210A is below atmospheric pressure. As an example, the pressure in sealed cavities 210A may range from about 0.1 Torr to about 700 Torr. In one example, the pressure in sealed cavity 210A is about 10 Torr. The type of substance or material within sealed cavities 210A is not a limitation of the present invention. For example sealed cavities 210A may contain a solid matter or a fluid such as a gas or a liquid.

Referring back to FIG. 9, the portions of capping structure 244, silicon nitride layer 52 and silicon dioxide layer 50 in active regions 20 and 21 are removed after the formation of dielectric platform 250. Active and passive semiconductor devices may be formed in or from the portions of substrate 14 adjacent dielectric platform 250. In addition, active or passive circuit elements, or portions thereof, may be formed on dielectric platform 250. By way of example, a passive circuit element 252 is formed on dielectric platform 250.

FIG. 15 is a cross-sectional view of a semiconductor structure 300 illustrating a dielectric platform (“DP”) 310, active regions 20 and 21, and an electrically conductive material 312 in accordance with another embodiment of the present invention. Dielectric platform 310 may be referred to as a dielectric structure or a dielectric region, and active regions 20 and 21 may also be referred to as active area regions or portions of an active area.

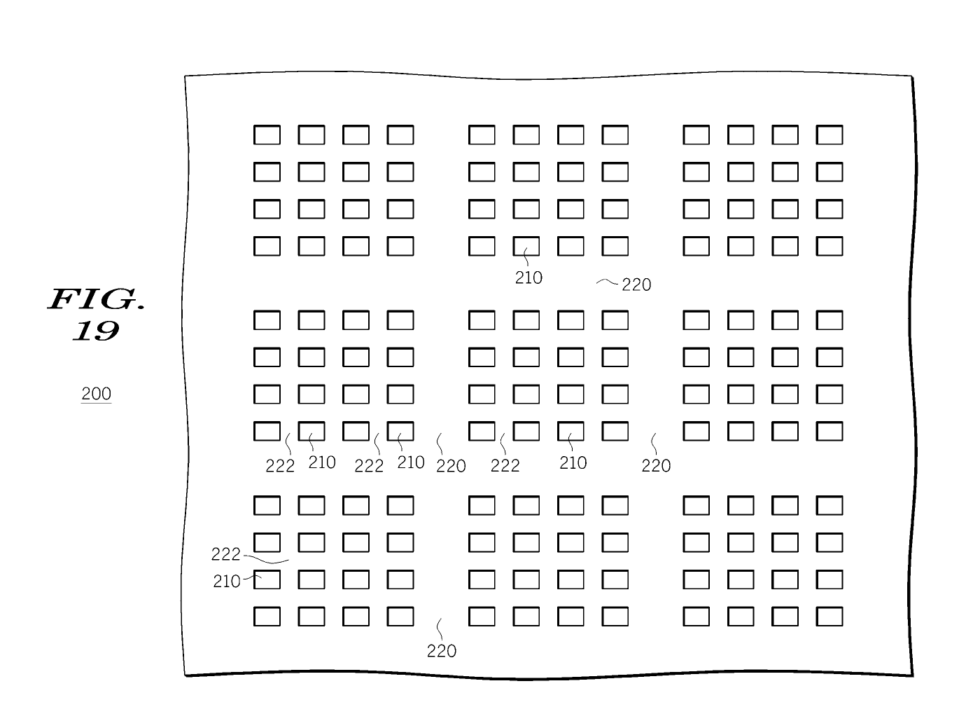

Dielectric platform 310 of semiconductor structure 300 comprises a plurality of dielectric hanging structures 232 extending into sealed cavities 210A, dielectric material 230 having protrusions 231, portions of layers 52 and 50, layers 304, and sealing layers 306. Substrate 14 has been described with reference to FIG. 1. Some projections 231 are spaced apart from each other by sealed cavities 210A and other projections 231 are spaced apart from each other by layer 304 and sealing layer 306. Sealed cavities 210A may be hermetically sealed under vacuum. However, air or another fluid may be within sealed cavities 210A. A capping structure 308 (FIG. 18) is formed over or covers dielectric hanging structures 232 to form sealed cavities 210A. Cavities 210 may also be referred to as gaps, air gaps, openings, empty regions, empty spaces or the like. When sealed, the cavities are identified by reference character 210A and may be referred to as sealed voids, sealed air gaps, sealed cavities, closed cells, or closed cell voids. The dimensions and advantages of dielectric platform 310 are the same as those of dielectric platform 18 which have been described with reference to FIG. 1.

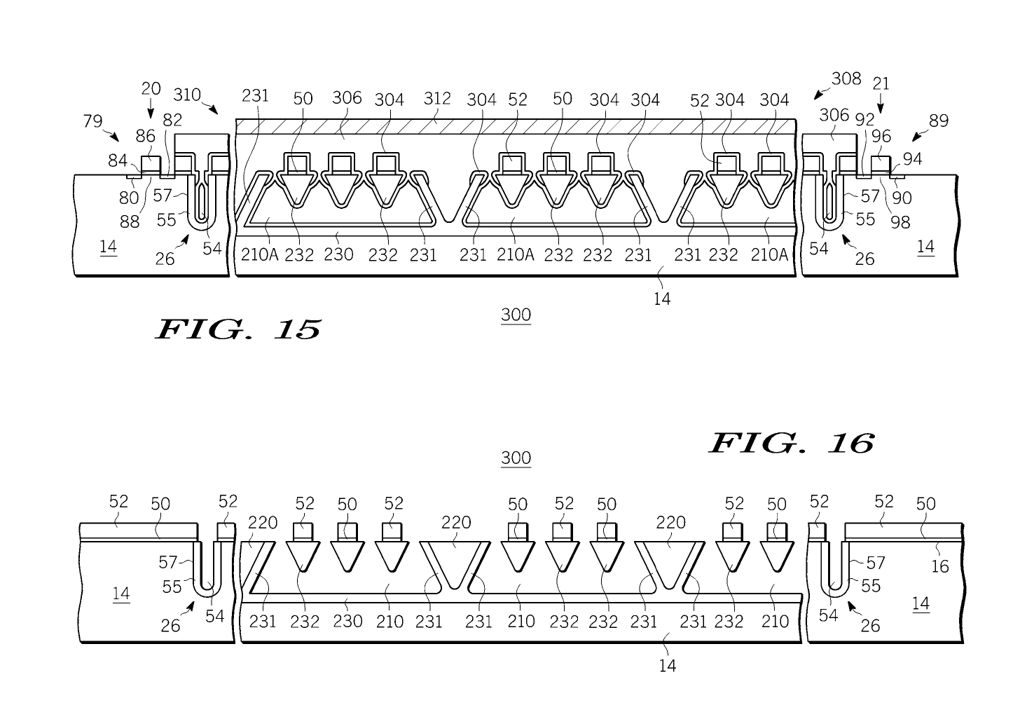

FIG. 16 is a cross-sectional view of semiconductor structure 300 during manufacture in accordance with another embodiment of the present invention. It should be noted that the steps illustrated and described with reference to FIGS. 10-13 for manufacturing semiconductor structure 200 may be the same as those for manufacturing semiconductor structure 300. Accordingly, the description for the manufacturing step shown in FIG. 16 continues from the description of FIG. 13. Referring now to FIG. 16, the portions of silicon nitride layer 52 and silicon dioxide layer 50 over support structures 220 are removed. In accordance with one embodiment, a layer of photoresist (not shown) is dispensed on the remaining portions of silicon nitride layer 52, cavities 210, the dielectric hanging structures 232 that are between projections or arms 231, and termination structures 26. The layer of photoresist is patterned to form masking structures (not shown) having openings that expose the portions of silicon nitride layer 52 over support structures 220. Thus, the portions of silicon nitride layer 52 that are over support structures 220 are unprotected by the layer of photoresist and removed using techniques for removing silicon nitride and silicon dioxide that are known to those skilled in the art. Removing the silicon nitride and silicon dioxide exposes the semiconductor material of support structure 220.

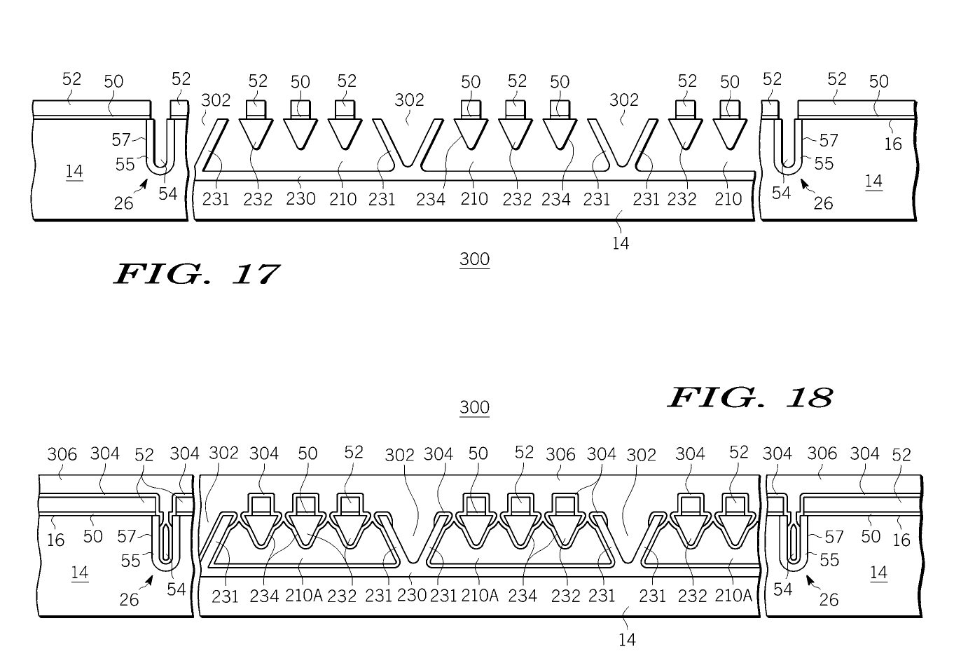

Referring now to FIG. 17, the exposed silicon material of support structures 220 is removed using, for example, a reactive ion etch, leaving openings 302 between adjacent projections 231. The layer of photoresist is removed.

Referring now to FIG. 18, a non-conformal layer of dielectric material 304 is formed on layer 52, portions of sidewalls 234 of dielectric hanging structures 232, and portions of projections 231. Layer 304 may comprise oxide, phosphosilicate glass (PSG), borophosphosilicate glass (“BPSG”), borosilicate glass (“BSG”), silicon nitride, or silicon oxynitride. Dielectric layer 304 decreases the distance between dielectric hanging structures 232, thereby reducing the openings between dielectric hanging structures 232. A portion of layer 304 may enter cavities 210 and become deposited on portions of sidewalls 234 and projections 231. In some embodiments, layer 304 does not fill cavities 210 and reduces openings 302. Layer 304 may or may not completely fill openings 302.

A layer of dielectric material 306 is formed on layer 304 and along sidewalls of cavities 210. Layer 306 may be a conformal layer that hermetically seals cavities 210 and trenches 54. Sealed cavities are identified by reference character 210A. Thus, layer 306 is referred to as a sealing layer. In other words, conformal layer 306 may fill any openings or cracks in layer 304, and in general prevent the propagation of gases or moisture into sealed cavities 210A. By way of example, sealing layer 306 comprises silicon nitride (“Si₃N₄”). In other embodiments, sealing layer 306 comprises LPCVD low temperature oxide (LTO), LPCVD high temperature oxide (HTO), LPCVD TEOS, or LPCVD PSG. Layer 304 in combination with sealing layer 306 form capping structure 308. Capping structure 308 may have a thickness ranging from about 1,000 Å to about 4 μm. In some embodiments, due to the relatively small openings between the upper portions of dielectric hanging structures 232, layer 304 may enter into a portion of one or more cavities 210 or a region between the upper portions of adjacent dielectric hanging structures 232, but not fill the one or more cavities 210. Similarly, in some embodiments, a portion of layer 304 may partially enter trenches 54 but not fill trenches 54.

Referring back to FIG. 15, the portions of capping structure 308, silicon nitride layer 52 and silicon dioxide layer 50 in active regions 20 and 21 are removed after the formation of dielectric platform 310. Active and passive semiconductor devices may be formed in or from the portions of substrate 14 adjacent dielectric platform 310. In addition, active or passive circuit elements, or portions thereof, may be formed on dielectric platform 310. By way of example, a passive circuit element 312 is formed on dielectric platform 310.

Accordingly, as has be discussed herein, the profile of the etched features of a dielectric platform can be varied by varying the etch parameters during the course of the etch process. For example, the taper of structures of the silicon substrate can be such that at some points in the structure the silicon is completely removed from the lower portions to form membrane of features (such as, for example, hanging structures 70) that are suspended over a cavity and connected to the silicon substrate only a the edges or periphery of the dielectric platform. An advantage of the disclosed dielectric platform structures include relatively less remaining silicon, which can reduce the induced stress upon oxidation, and can also result in more empty space in the dielectric platform leading to a relatively lower dielectric constant. Another advantage of the disclosed dielectric platform includes use of relatively smaller lithography dimensions which can result in a structure that has significant empty space in the dielectric platform with narrower surface openings. The narrower surface openings can make it easier to cap the empty space. Yet another advantage of this structure is that the membrane is more compliant compared to a structure that is anchored to the bottoms or floors of the cavities. This may result in increased accommodation of oxidation-induced stress by movement of the membrane components.

In addition, making mask openings, or etch openings, of different sizes can result in different etch rates resulting in different etched depths. For example, smaller mask openings can result in a lower etched rate than larger openings so that a smaller mask opening can generate a feature, such as a cavity, that has shorter depth compared to a larger mask opening that can generate a cavity having a relatively greater depth. Accordingly, the dielectric platforms disclosed herein that have suspended structures can be formed by varying line widths and spaces.

Accordingly, various structures and methods have been disclosed to provide a relatively thick, embedded dielectric platform that may be a dielectric support structure capable of supporting one or more passive devices over the dielectric platform. In various embodiments, the disclosed dielectric platform may provide electrical isolation, reduce parasitic substrate capacitance, allow for the formation of passive devices having a relatively high Q, and enable relatively higher frequency of operation or relatively higher breakdown voltages of any devices formed using, or in conjunction with, a structure that includes the dielectric platform. In addition, the disclosed dielectric platform and the methods for making the dielectric platform may reduce thermal stress that may be imparted to regions adjacent to the dielectric platform compared to other techniques and structures.

Although specific embodiments have been disclosed herein, it is not intended that the invention be limited to the disclosed embodiments. Those skilled in the art will recognize that modifications and variations can be made without departing from the spirit of the invention. It is intended that the invention encompass all such modifications and variations as fall within the scope of the appended claims.

What is claimed is:

1. A method to form a semiconductor structure, comprising:
removing a portion of a semiconductor material to form one or more suspended structures and a cavity, the cavity having a boundary that is below a surface of the semiconductor material, wherein the one or more suspended structures extend from the surface into the cavity;
altering the one or more suspended structures to form one or more altered suspended structures; and
forming a material over the one or more altered suspended structures and in a region between the one or more altered suspended structures.

2. The method of claim 1, wherein removing a portion of a semiconductor material to form one or more suspended structures and a cavity includes forming first and second suspended structures, wherein the first and second suspended structures are laterally spaced apart from each other by a first distance.

3. The method of claim 2, wherein the first and second suspended structures comprise silicon and wherein altering the one or more suspended structures includes oxidizing the first and second suspended structures so that the one or more altered suspended structures are spaced apart by a second distance.

4. The method of claim 3, wherein oxidizing the first and second suspended structures substantially converts the first and second suspended structures to silicon dioxide and wherein the second distance is less than the first distance.

5. The method of claim 1, wherein removing the portion of the semiconductor material to form one or more suspended structures and the cavity includes forming the one or more suspended structures to have tapered sidewalls.

6. The method of claim 1, wherein removing the portion of the semiconductor material includes forming a plurality of cavities in the semiconductor material.

7. The method of claim 6, wherein removing the portion of the semiconductor material includes forming a plurality of suspended structures in each cavity of the plurality of cavities.

8. The method of claim 6, wherein removing the portion of the semiconductor material includes forming a plurality of suspended structures in at least one cavity of the plurality of cavities.

9. The method of claim 1, wherein removing the portion of the semiconductor material includes forming at least one projection extending from the boundary of the cavity to a surface of the semiconductor material.

10. The method of claim 9, wherein forming the at least one projection extending from the boundary of the cavity to the surface of the semiconductor material includes forming first and second projections.

11. The method of claim 10, wherein the one or more suspended structures is between the first and second projections.

12. The method of claim 11, wherein forming the at least one projection includes forming a third projection, the second projection between the first and third projections and wherein the one or more suspended structures are absent from the region between the second and third projections.

13. The method of claim 1, wherein forming the material over the one or more suspended structures and in the region between the one or more altered suspended structures includes forming a first dielectric material over the one or more altered suspended structures and in the region between the one or more altered suspended structures.

14. The method of claim 13, further including hermetically sealing the cavity.

15. The method of claim 14, wherein hermetically sealing the cavity includes forming a second dielectric material over the first dielectric material.

16. The method of claim 15, wherein the first dielectric material comprises silicon dioxide and the second dielectric material comprises silicon nitride or an oxide.

17. The method of claim 1, further including forming a termination structure in the semiconductor material and adjacent a periphery of the cavity, wherein forming the termination structure includes forming a trench in the semiconductor material and performing a thermal oxidation process to form a dielectric material along a sidewall of the trench.

18. A method to form a semiconductor structure, the method comprising:
providing a semiconductor material having a surface;
forming one or more cavities in the semiconductor material, the one or more cavities having a floor;
forming one or more hanging structures in at least one of the one or more cavities, the one or more hanging structures extending from the surface of the semiconductor material;
enlarging the one or more hanging structures to form one or more enlarged hanging structures; and
covering the one or more enlarged hanging structures.

19. The method of claim 18, wherein covering the one or more enlarged hanging structures includes forming a first layer of dielectric material over the one or more enlarged hanging structures.

20. The method of claim 19, further including sealing the one or more cavities.

21. The method of claim 20, wherein sealing the one or more cavities includes hermetically sealing the one or more cavities by forming a second layer of dielectric material over the first layer of dielectric material.

22. The method of claim 18, wherein forming the one or more cavities and forming the one or more hanging structures includes etching the semiconductor material to simultaneously form the one or more cavities and the one or more hanging structures.

23. The method of claim 22, further including forming at least one projection extending from the floor to the surface of the semiconductor material.

24. The method of claim 18, wherein forming the at least one projection includes forming first and second projections extending from the floor to the surface of the semiconductor material, wherein a first cavity of the one or more cavities is between the first and second projections.

25. The method of claim 24, wherein forming the at least one projection includes forming a third projection.

26. The method of claim 25, further including forming an opening between the second and third projections by removing a portion of the semiconductor material.

27. The method of claim 26, further including forming a dielectric material in the opening.

28. A semiconductor structure, comprising:
a semiconductor material having a surface;
a first cavity extending from the surface into the substrate, the first cavity having a boundary that is parallel to, or substantially parallel to, the surface;
a first dielectric structure extending from the surface of the semiconductor material into the first cavity, the first dielectric structure is spaced apart from the boundary; and
a capping structure over the first dielectric structure and the first cavity.

29. The semiconductor structure of claim 28, further including
a first dielectric projection extending from the boundary to the surface.

30. The semiconductor structure of claim 29, further including a second dielectric projection spaced apart from the first dielectric projection and wherein a portion of the capping structure is between the first and second dielectric projections.

31. The semiconductor structure of claim 30, further including a third dielectric projection extending from the boundary to the surface, wherein the first dielectric structure extending from the surface into the first cavity is between the second and third dielectric projections.

32. The semiconductor structure of claim 28, wherein the capping structure comprises a second layer of dielectric material on a first layer of dielectric material.

33. The semiconductor structure of claim 28, further including a second dielectric structure extending from the surface of the semiconductor material into the first cavity, wherein the second dielectric structure is spaced apart from the boundary, wherein the capping structure is over the second dielectric structure and is in a region between the first dielectric structure and the second dielectric structure, wherein the capping structure includes a first dielectric material over the first dielectric structure and the second dielectric structure and a second dielectric material over at least a portion of the first dielectric material, and wherein the first dielectric layer comprises an oxide and the second dielectric material comprises silicon nitride.

34. The semiconductor structure of claim 28, further including a second cavity extending from the surface into the substrate and isolated from the first cavity.
